(19) United States
(12) Patent Application Publication
(10) Pub. No.: US 2026/0372040 A1
(43) Pub. Date: Nov. 19, 2026

(54) METHODS FOR FORMING METAL INTERCONNECTS

(71) Applicant: Tokyo Electron Limited, Tokyo (JP)

(72) Inventors: Andrew Tuchman, Albany, NY (US); Hirokazu Aizawa, Albany, NY (US); Joshua Mayersky, Albany, NY (US); Christopher Michael Netzband, Albany, NY (US); Ilseok Son, Albany, NY (US)

(21) Appl. No.: 19/212,347

(22) Filed: May 19, 2025

(51) Int. Cl. H10W 20/00; H10W 20/41

(52) U.S. Cl. CPC H10W 20/064; H10W 20/062; H10W 20/063; H10W 20/425

(57) ABSTRACT

A method is provided for forming a semiconductor device. The method includes depositing a metal layer on a carrier wafer. The metal layer is annealed at an elevated temperature to form oriented grain structures in the metal layer. A device wafer including an active region is provided. The metal layer is bonded to the active region of the device wafer. The carrier wafer is removed after the bonding process. The metal layer is etched to form a plurality of metal lines.

### TECHNICAL FIELD

The present invention relates generally to a method for semiconductor device manufacturing, and, in particular embodiments, to a method for forming metal interconnects.

### BACKGROUND

Metal interconnects, particularly metal lines, serve as the vital conductive pathways that electrically connect various components within integrated circuits. These structures transport electrical signals and power throughout semiconductor devices, making them essential for proper device functionality and performance. As semiconductor technology advances toward greater integration density and higher performance requirements, the electrical characteristics of these metal lines become increasingly important. Conventional interconnect fabrication may involve either subtractive etching of deposited metal films or damascene processes where metal is deposited into pre-patterned trenches. The quality and microstructure of these metal lines directly impact device performance metrics including signal propagation speed, power consumption, and overall reliability.

Ruthenium, molybdenum, and other refractory metals have emerged as promising alternatives to traditional copper interconnects. While copper offers lower bulk resistivity in larger dimensions, its electrical performance degrades significantly at nanoscale dimensions due to increased electron scattering at grain boundaries and interfaces. Refractory metals can provide lower effective resistivity at these reduced dimensions due to their favorable electron mean free path characteristics and potential for larger grain sizes relative to line dimensions. Additionally, these metals offer enhanced electromigration resistance and may require thinner or no diffusion barriers compared to copper. As device scaling continues to push interconnect dimensions toward atomic-scale limits, the inherent advantages of these alternative metals become increasingly important for maintaining electrical performance and reliability.

### SUMMARY

In accordance with one aspect of the present invention, a method is provided for forming a semiconductor device. The method includes depositing a metal layer on a carrier wafer and annealing the metal layer at an elevated temperature to form oriented grain structures in the metal layer. The method further includes providing a device wafer comprising an active region and bonding the metal layer to the active region. The carrier wafer is then removed, and the metal layer is etched to form a plurality of metal lines.

In accordance with another aspect of the present invention, a method is provided for forming a semiconductor device. The method includes depositing an underlayer on a carrier wafer, a first adhesion layer on the underlayer, and a metal layer on the first adhesion layer. The metal layer is annealed at an elevated temperature to form oriented grain structures in the metal layer. The metal layer is bonded to an active region of a device wafer. The method further includes removing the carrier wafer to expose the underlayer, patterning the underlayer to form a patterned hard mask, and etching the metal layer through the patterned hard mask to form a plurality of metal lines.

In accordance with yet another aspect of the present invention, a method is provided for forming a semiconductor device. The method includes providing a first bonding structure comprising a metal layer on a carrier wafer and annealing the first bonding structure at an elevated temperature to form oriented grain structures in the metal layer. The metal layer is exposed to a plasma to smoothen a surface of the metal layer. The method further includes providing a second bonding structure comprising an active region on a device wafer and forming a bonded structure by bonding the first bonding structure to the second bonding structure, wherein the metal layer is bonded to the active region. The carrier wafer is removed, and the metal layer is etched to form a plurality of metal lines.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1J illustrate cross-sectional views of a process for forming metal interconnects using a wafer-to-wafer transfer method, in accordance with an embodiment;

FIGS. 2A-2B illustrate top-down views comparing grain structures of a metal layer before and after annealing, in accordance with an embodiment;

FIGS. 3A-3B illustrate cross-sectional views of a plasma activation process for surface smoothing after annealing, in accordance with an embodiment;

FIGS. 4A-4B illustrate cross-sectional views of an alternative embodiment for bonding without a second adhesion layer, in accordance with an embodiment; and

FIG. 5 illustrates a process flowchart of forming metal interconnects through the wafer-to-wafer transfer method, in accordance with an embodiment.

### DETAILED DESCRIPTION OF ILLUSTRATIVE EMBODIMENTS

As semiconductor device dimensions continue to shrink below 20 nanometers, metal interconnects face challenges of reduced electrical resistance. At ultra-low pitches below 20 nanometers, electrical resistance is predominantly governed by electron scattering at grain boundaries and liner interfaces rather than the bulk resistivity of the metal. Larger metal grains are highly desirable for reducing resistance by minimizing grain boundary scattering; however, conventional back-end-of-line (BEOL) processing imposes strict temperature limitations (e.g., below 400 °C) to prevent damage to underlying device structures. These temperature constraints make it difficult to form large, highly oriented metal grains necessary for lower electrical resistance.

Embodiments of the present disclosure address these challenges through a wafer-to-wafer layer transfer approach. The process may involve depositing a metal film stack on a separate carrier wafer, followed by high-temperature annealing (approximately 1000 °C) to form a highly oriented metal structure with significantly reduced grain boundaries and defects. This processed metal layer may be subsequently transferred to the device wafer through wafer bonding techniques that operate below 400 °C, compatible with BEOL process. In some embodiments, the carrier wafer may be removed using a conventional wafer grinding process after bonding. In alternative embodiments, the carrier wafer may be removed using laser lift-off techniques after bonding, which allows the carrier wafer to be reused for subsequent processing, eliminating the waste associated with conventional grinding methods. The transferred highly oriented metal layer may be then patterned using subtractive etching to form the final interconnect structures.

By separately annealing the metal layer on a carrier wafer, the wafer-to-wafer transfer approach may bypass the temperature limitations of BEOL processing. The resulting metal lines may exhibit substantially lower electrical resistance (below 10 μΩ·cm) due to reduced electron scattering at grain boundaries, enabling performance improvements for advanced semiconductor devices.

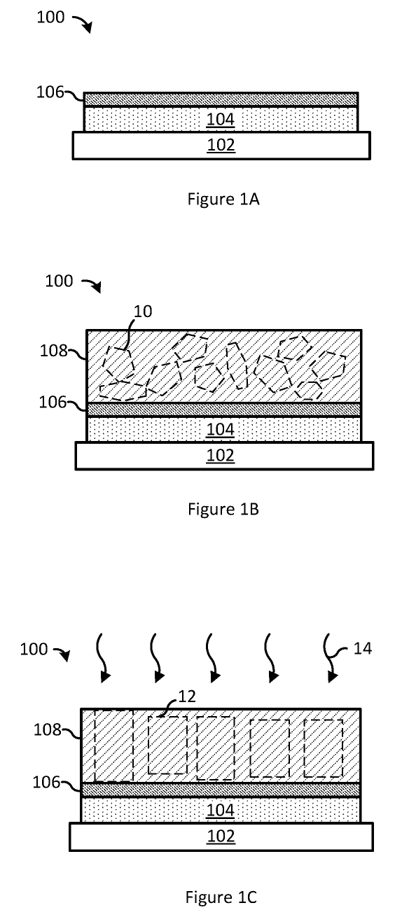

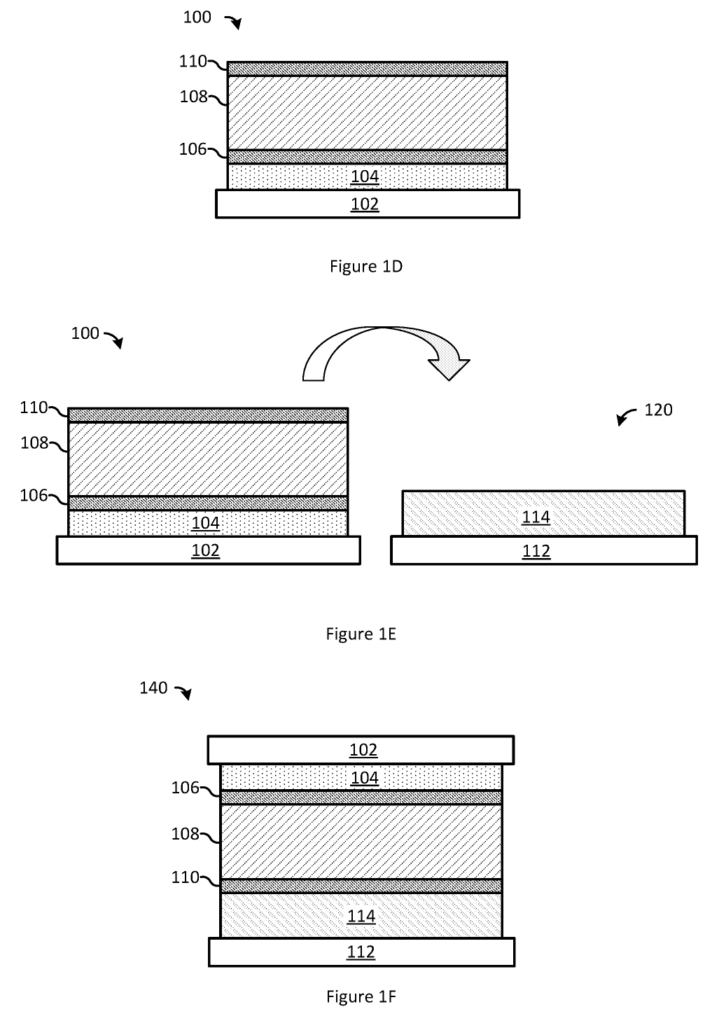

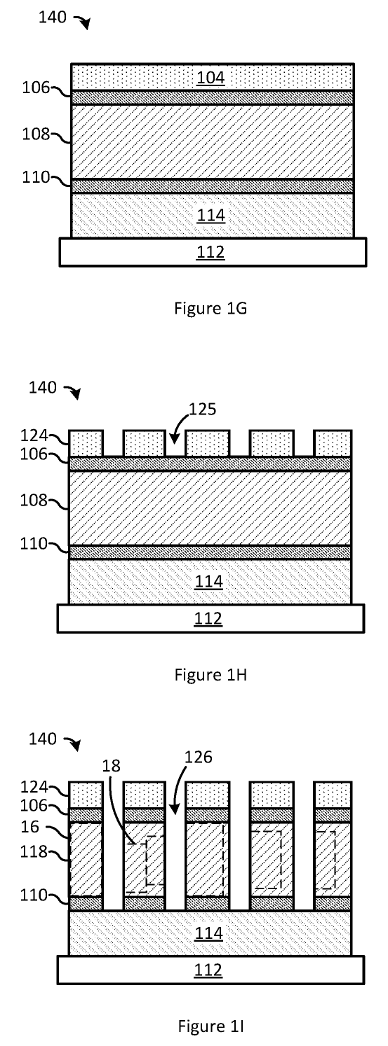

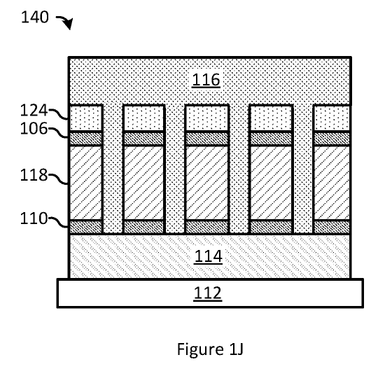

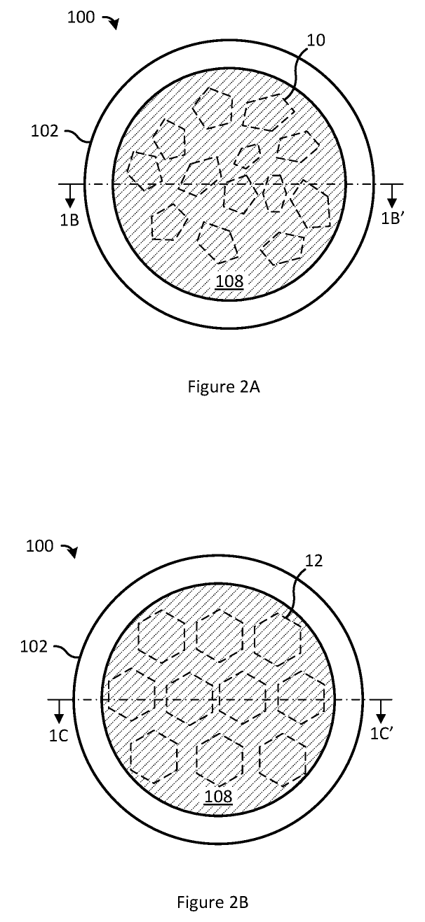

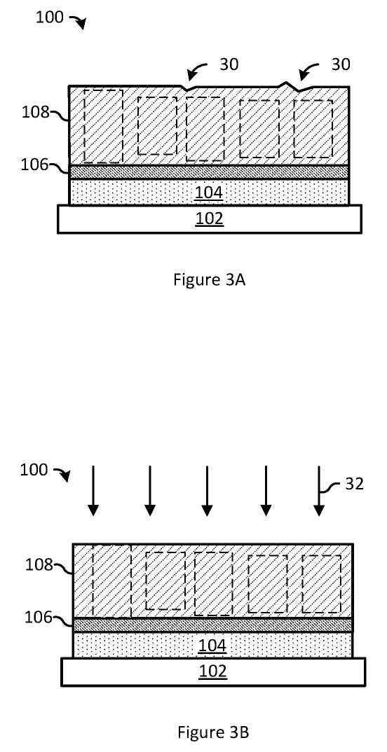

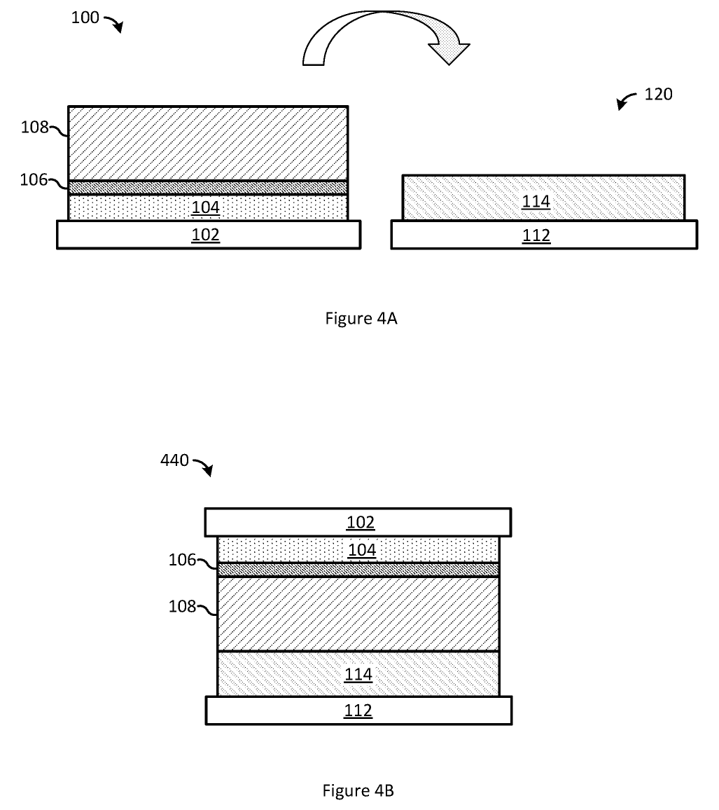

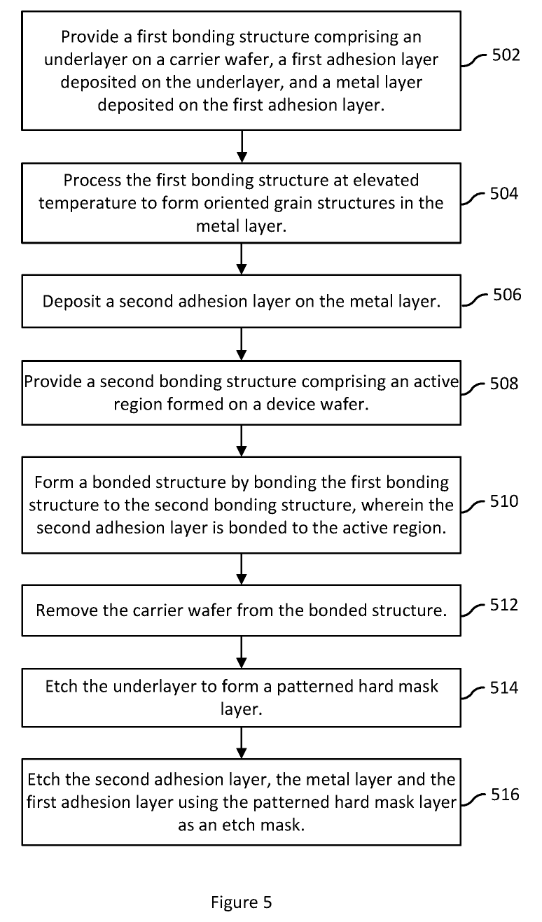

Embodiments of the disclosure are described in the context of the accompanying drawings. A process flow for forming highly oriented metal films using a wafer-to-wafer transfer method is illustrated in FIGS. 1A-1J, showing the progression from initial layer deposition through annealing, bonding, carrier removal, and etching to form metal lines with optimized grain structures. Top-down views comparing disoriented grain structure before annealing to oriented grain structure after annealing are presented in FIGS. 2A-2B, illustrating the transformation from small and irregular grains to large and oriented grains with reduced boundaries. An embodiment of plasma activated surface smoothing after the annealing and before the bonding is shown in FIGS. 3A-3B. A variation of the process that skips the second adhesion layer deposition is illustrated in FIGS. 4A-4B, showing direct bonding of the metal layer to a device wafer. A flowchart illustrating process steps for the wafer-to-wafer transfer method is provided in FIG. 5, outlining the sequence from initial structure formation through final etching.

FIGS. 1A-1J illustrate cross-sectional views of a process for forming metal interconnects with highly oriented grain structures using a wafer-to-wafer transfer method, in accordance with an embodiment.

In FIG. 1A, a first bonding structure 100 may be provided in a process chamber. In various embodiments, the first bonding structure 100 may comprise an underlayer 104 deposited on the carrier wafer 102, and a first adhesion layer 106 deposited on the underlayer 104.

In one or more embodiments, the carrier wafer 102 may comprise a semiconductor material such as silicon, silicon carbide, or silicon-on-insulator (SOI). In various embodiments, the carrier wafer 102 may have a specific crystallographic orientation, such as (100), (110), or (111) silicon, selected to promote desired crystallographic growth in subsequent layers. For example, a (111) oriented silicon carrier wafer may be selected to promote epitaxial-like growth of certain metals with hexagonal close-packed (HCP) structures, such as ruthenium, resulting in highly oriented films with reduced grain boundaries. This crystallographic engineering is advantageous over conventional back-end-of-line (BEOL) processes, where the substrate orientation may be predetermined by front-end-of-line (FEOL) requirements and limited to (100) silicon. The ability to select optimal crystal orientations for the carrier wafer 102 enables microstructural control of subsequently deposited material layers that may be challenging with direct deposition on device wafers.

In alternative embodiments, the carrier wafer 102 may comprise sapphire, quartz, glass, or engineered templates with specific surface structures. Ceramic substrates such as aluminum nitride or aluminum oxide may also be employed as carrier wafers when their thermal expansion characteristics or crystallographic properties offer advantages for specific metal film orientations. In some embodiments, composite or layered substrate materials may be used to optimize both the thermal stability during high-temperature annealing and the subsequent laser lift-off efficiency. The carrier wafer 102 may provide a temporary substrate for high-temperature annealing that may otherwise exceed the thermal budget of device wafers with existing active regions.

In various embodiments, the underlayer 104 may comprise dielectric materials such as silicon oxide, titanium oxide, titanium nitride, silicon carbide, or silicon nitride, or combinations thereof. In an embodiment, the underlayer 104 may be deposited using chemical vapor deposition (CVD), plasma-enhanced chemical vapor deposition (PECVD), atomic layer deposition (ALD), or physical vapor deposition (PVD) techniques. In one or more embodiments, the thickness of the underlayer 104 may range from approximately 5 nm to 50 nm. The underlayer 104 may provide a controlled surface for subsequent metal deposition, act as a diffusion barrier between the carrier wafer 102 and overlying layers, and later serve as a hard mask material for patterning metal films.

In various embodiments, the first adhesion layer 106 may comprise materials such as titanium nitride (TiN), tantalum nitride (TaN), niobium (Nb), or other refractory metals or their compounds. In various embodiments, the first adhesion layer 106 may be deposited using PVD, CVD, or ALD techniques with thicknesses ranging from approximately 2 nm to 20 nm. The first adhesion layer 106 may enhance adhesion between the underlayer 104 and a subsequently deposited metal layer. The first adhesion layer 106 may also promote specific crystallographic orientation in the metal layer, and provide strain accommodation during high-temperature annealing. In one or more embodiments, the composition and thickness of the first adhesion layer 106 may be tailored to control the orientation of the subsequently deposited metal layer, influencing the grain structure development during annealing. For example, a 3-5 nm titanium nitride-based adhesion layer with (111) preferred orientation deposited by reactive sputtering may promote (0001) orientation in a subsequently deposited ruthenium layer, while a 2 nm niobium-based adhesion layer may promote different crystallographic orientations in the same ruthenium film. The crystallographic relationship between the adhesion layer and metal film can be further enhanced through specific deposition parameters such as substrate bias, deposition temperature, and pressure, which affect the nucleation and growth modes of the metal film.

In FIG. 1B, a metal layer 108 may be deposited on the first adhesion layer 106, in accordance with an embodiment. In various embodiments, the metal layer 108 may comprise disoriented grain structures 10 characterized by small grain size and high density of grain boundaries. In some embodiments, the metal layer 108 may be deposited on the underlayer 104 directly without the first adhesion layer 106.

In one or more embodiments, the metal layer 108 may comprise ruthenium, molybdenum, cobalt, tungsten, or other refractory metals suitable for advanced metal interconnect applications. Refractory metals may have high melting points (e.g., above 2000 °C), excellent thermal stability, and superior resistance to electromigration compared to conventional copper interconnects. Refractory metals may be particularly advantageous for advanced semiconductor devices with ultra-narrow interconnect dimensions. While copper offers lower bulk resistivity in larger interconnect structures, its performance degrades significantly at dimensions below 20 nm due to increased electron scattering at grain boundaries and interfaces, as well as the requirement for relatively thick diffusion barriers that consume precious cross-sectional area. In one embodiment, the metal layer 108 comprising ruthenium may offer favorable electron mean free path characteristics and can potentially operate without the thick diffusion barriers required for copper, effectively providing more conductive material within the same dimensional constraints. In another embodiment, the metal layer 108 comprising molybdenum may provide excellent electromigration resistance and thermal stability, with a body-centered cubic (BCC) structure that can be oriented to minimize grain boundary scattering.

In various embodiments, the metal layer 108 may be deposited using physical vapor deposition (PVD), chemical vapor deposition (CVD), atomic layer deposition (ALD), or electroplating techniques. The thickness of the metal layer 108 may range from approximately 20 nm to 100 nm, depending on the specific interconnect requirements. For ultra-narrow interconnects with dimensions below 20 nm, thinner metal layers may be employed to facilitate subsequent patterning processes.

In one or more embodiments, the metal layer 108 after initial deposition may exhibit the disoriented grain structures 10 with relatively small grain sizes, varying orientations, irregular shapes, and a high density of grain boundaries. The disoriented grain structures 10 may result from the limited adatom mobility during conventional deposition processes at temperatures compatible with standard semiconductor manufacturing. In one or more embodiments, the disoriented grain structures 10 may comprise randomly oriented crystallites with varying sizes, for example, in the range of 5-15 nm. The high density of grain boundaries in this initial structure may contribute to increased electron scattering and higher electrical resistivity if used directly for interconnect applications.

FIG. 2A illustrates a top-down view of the first bonding structure 100 corresponding to the cross-sectional view shown in FIG. 1B, in accordance with an embodiment. The figure provides a planar perspective of the metal layer 108 with disoriented grain structures 10 after deposition. A cross-sectional plane indicated by line 1B-1B’ corresponds to the view presented in FIG. 1B.

From this top-down perspective, the disoriented grain structures 10 of the metal layer 108 may be characterized by numerous small grains with irregular shapes and random crystallographic orientations. The grain boundaries may appear as a dense network throughout the metal layer 108, creating multiple interfaces where electron scattering would occur during electrical conduction. The disoriented nature of the grain structure is evident from the random arrangement of grain boundaries, lacking any preferred directionality or alignment. This randomness may result from the limited surface mobility of metal atoms during conventional deposition processes, where atoms may be restricted in position upon contacting the surface rather than migrating to energetically favorable sites that would promote crystallographic alignment.

The high density of grain boundaries visible in this top-down view directly correlates with increased electrical resistivity. Each grain boundary represents a disruption in the crystalline lattice where conduction electrons experience scattering, impeding their flow and increasing resistivity. For interconnect applications at dimensions below 20 nanometers, this grain boundary scattering may become the dominant factor limiting electrical performance, rather than the intrinsic resistivity of the metal itself.

Referring back to FIG. 1C. FIG. 1C illustrates a cross-sectional view of the first bonding structure 100 after an annealing process 14 is applied to transform the metal layer 108, in accordance with an embodiment. The annealing process 14 may convert the initially disoriented grain structures 10 shown in FIG. 1B into oriented grain structures comprising enlarged grain sizes and reduced density of grain boundaries.

The annealing process 14 may be implemented through various heating methods to achieve the elevated temperatures required for grain growth and reorientation. In one or more embodiments, substrate holder heating may be employed, where the carrier wafer 102 is placed on a heated substrate holder containing embedded resistive heating elements or lamp-based heating systems capable of achieving temperatures up to approximately 1200 °C with precise temperature control. In alternative embodiments, the annealing process 14 may utilize a batch furnace system, where multiple carrier wafers may be processed simultaneously in a controlled thermal environment. In one or more embodiments, rapid thermal processing (RTP) using high-intensity halogen or arc lamps, microwave annealing for volumetric heating, or flash lamp annealing delivering millisecond-duration energy pulses may be employed to achieve the desired microstructural transformation.

In various embodiments, the annealing temperature may range between 800 °C and 1200 °C, with an upper limit selected to avoid potential intermixing between the metal layer 108 and silicon from the carrier wafer 102. At temperatures above approximately 1200 °C, there may be increased risk of silicon diffusion into the metal layer or metal diffusion into silicon, which could compromise the purity and performance of the metal film. The specific temperature may be selected based on the particular metal composition, with higher melting point metals like tungsten potentially benefiting from temperatures closer to the upper limit of this range.

The annealing atmosphere plays an important role in preventing oxidation and promoting desirable grain growth. In various embodiments, a forming gas environment consisting of 4% hydrogen in nitrogen or argon may be used to provide a mildly reducing atmosphere that prevents oxidation of the metal surface while facilitating atomic rearrangement at grain boundaries. For certain metals more susceptible to oxidation, higher hydrogen concentrations or pure hydrogen atmospheres may be employed with appropriate safety measures. The annealing duration may range from several minutes to hours depending on the specific metal, temperature, and desired grain size.

During the annealing process 14, the oriented grain structures 12 may develop through several mechanisms. The high temperature may provide sufficient thermal energy for atoms to overcome diffusion barriers and reorganize at grain boundaries. Smaller grains with higher surface energy tend to be consumed by larger grains, resulting in overall grain growth. Concurrently, the crystallographic orientation of the grains may evolve toward preferred low-energy configurations, which may be influenced by the underlying first adhesion layer 106. In some embodiments, columnar grain structures with grains preferentially oriented perpendicular to the substrate surface may extend vertically through the thickness of the metal layer 108.

In one or more embodiments, the oriented grain structures 12 may comprise vertical arrangement of the crystal structure, particularly beneficial for electrical conduction in interconnect applications. When metal lines are subsequently patterned from this film, the grain boundaries may run parallel to the direction of current flow rather than perpendicular to it, effectively reducing electron scattering events. In an embodiment, the annealing parameters may be optimized to produce grains large enough that individual metal lines with widths below 20 nm may contain only a single grain across their width, effectively eliminating grain boundary scattering in the direction of current flow. The oriented grain structures 12 may exhibit reduced grain boundary density compared to the initial structure shown in FIG. 1B. In various embodiments, the oriented grain structures 12 may comprise grain sizes exceeding 50-100 nm in diameter. This microstructural transformation may reduce the electrical resistivity of the metal film to below 10 μΩ·cm.

FIG. 2B illustrates a top-down view of the first bonding structure 100 corresponding to the cross-sectional view shown in FIG. 1C, in accordance with an embodiment. The figure provides a planar perspective of the metal layer 108 with oriented grain structure 12 after the annealing process 14. A cross-sectional plane indicated by line 1C-1C’ corresponds to the view presented in FIG. 1C.

Comparing to the grain structures 10 shown in FIG. 2A, the oriented grain structure 12 comprises larger and more oriented grains with more homogeneous ordering throughout the film. This increased homogeneity may result from the thermodynamic driving forces during annealing that favor specific crystallographic orientations to minimize interfacial and surface energies. The more uniform grain size distribution and preferred orientation visible in this top-down view may directly correlate with improved electrical performance, as the reduced grain boundary density minimizes electron scattering sites. In advanced interconnect applications, this optimized grain structure can potentially enable individual metal lines or vias to span across entire grains, effectively eliminating grain boundary scattering in the current-carrying direction.

In one or more embodiments, the oriented grain structure 12 may appear as hexagons or other polygonal shapes depending on the specific crystal structure of the metal. The grain boundaries may be reduced in total length and density compared to after deposition shown in FIG. 2A. In some embodiments, the metal layer 108 may comprise face-centered cubic (FCC) metals, the grains may develop into truncated octahedrons that appear as irregular hexagons when viewed from the top. In embodiments where the metal layer 108 may comprise hexagonal close-packed (HCP) metals like ruthenium, more pronounced hexagonal patterns with 120° angles at grain junctions may be formed. In some embodiments, the metal layer 108 may comprise body-centered cubic (BCC) metals such as tungsten or molybdenum, more rectangular or square-like grain structures may be formed. The specific annealing parameters, including temperature ramp rates, hold times, and cooling profiles, can further influence these grain morphologies by affecting the balance between surface energy minimization and kinetic limitations during growth. In some cases, elongated grain structures may form due to directional thermal gradients during the annealing process, creating a microstructure with anisotropic electrical properties that could be advantageous for specific interconnect orientations.

It should be noted that the illustration of grain structures 10 and 12 in FIGS. 1B-1C, 2A-2B shows grains separated from each other for clarity of visualization. In practical applications, these grains are in direct contact with each other, forming continuous grain boundaries where their crystalline lattices meet. The figure is intended to illustrate the orientations, relative sizes, and density of grains rather than suggesting physical separation between adjacent grains. The actual microstructure would consist of a continuous metal film with internal grain boundaries defined by the interfaces between differently oriented crystalline regions.

FIG. 1D illustrates a cross-sectional view of the first bonding structure 100 after deposition of a second adhesion layer 110 on the metal layer 108 which may comprise oriented grain structures 12.

In various embodiments, the second adhesion layer 110 may comprise materials similar to those used for the first adhesion layer 106, such as titanium nitride (TiN), tantalum nitride (TaN), niobium (Nb), or other refractory metals or their compounds. In various embodiments, the second adhesion layer 110 may be deposited using physical vapor deposition (PVD), chemical vapor deposition (CVD), or atomic layer deposition (ALD) techniques. The thickness of the second adhesion layer 110 may range from approximately 2 nm to 20 nm, with thinner layers often preferred to minimize additional electrical resistance in the final interconnect structure.

In various embodiments, the second adhesion layer 110 may facilitate bonding between the metal layer 108 and a device wafer in subsequent processing steps. The second adhesion layer 110 may provide a controlled surface chemistry and topography that enhances bonding strength and reliability. The second adhesion layer 110 may also serve as a diffusion barrier, preventing potential intermixing between the metal layer 108 and materials on the device wafer during the bonding process.

In some embodiments, the surface of the second adhesion layer 110 may undergo additional treatments such as chemical-mechanical polishing (CMP), plasma activation, or chemical treatments to achieve the sub-nanometer surface roughness required for wafer bonding. These surface preparation steps may enhance the bonding energy and reduce the likelihood of interfacial voids or delamination in the bonded structure.

After deposition of the second adhesion layer 110, the first bonding structure 100 may be ready for the wafer-to-wafer bonding process that can transfer highly oriented metal layer 108 to a device wafer containing an active region with semiconductor devices formed in a front-end-of-line (FEOL) portion of the device wafer. This transfer approach enables the integration of the high-performance metal layer with conventional semiconductor devices while bypassing the thermal limitations that would otherwise prevent the formation of the optimized grain structure.

In FIG. 1E, a second bonding structure 120 may be provided in the process chamber and aligned with the first bonding structure 100 in preparation for wafer-to-wafer bonding. In various embodiments, the second bonding structure 120 may comprise a device wafer 112 with an active region 114 formed thereon.

In one or more embodiments, the device wafer 112 may comprise similar materials as the carrier wafer 102 as described previously. In some embodiments, the device wafer 112 may comprise silicon with standard semiconductor device structures fabricated using conventional FEOL processing. In some embodiments, the active region 114 may comprise the active devices such as transistors, diodes, resistors, and other semiconductor components that will be electrically connected through the metal interconnects formed from the metal layer 108. The device wafer 112 may have undergone numerous processing steps including ion implantation, thermal oxidation, gate formation, contact formation, and initial metallization prior to this bonding stage.

In preparation for bonding, the surfaces of both the first bonding structure 100 and the second bonding structure 120 may be cleaned and undergo surface activation treatments to enhance bonding strength. In various embodiments, these activation treatments may include plasma activation, chemical modification, or other surface preparation techniques that promote strong adhesion between the bonding surfaces. The surface roughness of both bonding structures (100 and 120) may be reduced to below 0.5 nm RMS (root mean square) to ensure intimate contact across the entire wafer surface during bonding.

FIG. 1F illustrates formation of a bonded structure 140 after a bonding process that bonds the first and the second bonding structures 100 and 120 together. In the bonded structure 140, the second adhesion layer 110 may be bonded to the active region 114 on the device wafer 112.

In various embodiments, the bonding process may be performed at temperatures below 400 °C to maintain compatibility with the thermal budget constraints of the active region 114. The bonding process may be accomplished through various techniques including direct bonding, thermocompression bonding, or plasma-activated bonding, depending on the specific materials involved and the required bond strength.

During the bonding process, the first and the second bonding structures 100 and 120 may be brought into intimate contact under controlled pressure and temperature conditions. The applied pressure ensures uniform contact across the entire structure surface, while the elevated temperature (though still below 400 °C) promotes interdiffusion and chemical bonding at the interface between the second adhesion layer 110 and the active region 114. In some embodiments, an intermediate bonding layer may be employed to enhance adhesion between specific material combinations.

FIG. 1G illustrates a process step of removing the carrier wafer 102, in accordance with an embodiment. In various embodiments, the carrier wafer 102 may be removed using a wafer grinding process or a laser lift-off process. The removing step may expose the underlayer 104, which is accessible for subsequent patterning operations.

In one or more embodiments, the wafer grinding process may begin with attaching the bonded structure 140 to a grinding support fixture, with the device wafer 112 facing downward and protected. A precision grinding wheel with selected abrasive particles (e.g., diamond or aluminum oxide) may then be used to mechanically thin the carrier wafer 102 from its backside. In some embodiments, the grinding process may be performed in multiple stages, beginning with a coarse grinding step to rapidly remove the bulk of the carrier wafer material, followed by finer grinding steps with progressively smaller abrasive particles to minimize subsurface damage. The grinding may continue until the carrier wafer 102 is either completely removed, exposing the underlayer 104, or thinned to a few micrometers, with the remaining material removed through subsequent chemical etching or chemical-mechanical polishing. After grinding, a surface cleaning step may be performed to remove any residual particles or contamination before proceeding to the patterning of the underlayer 104.

In various embodiments, the laser lift-off process may enable non-destructive separation of the carrier wafer 102 from the transferred first bonding structure 100. Different from conventional grinding or chemical etching methods, the laser lift-off process may reuse the carrier wafer 102 for subsequent processing, reduce waste generation, and minimize mechanical stress on the transferred layers.

In one or more embodiments, a laser beam with selected wavelength may be directed through the backside of the carrier wafer 102 during the laser lift-off process. The laser wavelength may be chosen to be transmitted through the bulk of the carrier wafer with minimal absorption, but strongly absorbed by the underlayer 104. In alternative embodiments, an absorption layer may be disposed between the carrier wafer 102 and the underlayer 104 to absorb the laser energy. When the laser energy is absorbed at the underlayer 104 or the absorption layer, it may cause rapid localized heating that leads to material decomposition, phase change, or gas formation, depending on the specific materials involved. The localized reaction may create a separation plane that allows the carrier wafer 102 to be cleanly detached from the rest of the structure. In some embodiments, the laser lift-off process may employ a pulsed laser with nanosecond or shorter pulse duration to minimize thermal diffusion into adjacent layers, ensuring that the highly oriented metal layer 108 remains unaffected by the separation process. In some embodiments, the laser beam may be scanned across the entire wafer area in a controlled pattern, progressively separating the carrier wafer 102 from the bonded structure 140. Alternatively, in some embodiments, a single large-area laser pulse may be used to initiate separation across the entire wafer simultaneously, followed by mechanical lifting of the carrier wafer 102.

After the laser lift-off process, the carrier wafer 102 can be reclaimed, reconditioned, and reused for subsequent processing cycles, providing significant cost advantages compared to destructive removal methods. The exposed underlayer 104 may undergo a cleaning step to remove any residual material from the separation interface and prepare the surface for subsequent lithography and patterning steps.

In FIG. 1H, the underlayer 104 of the bonded structure 140 may be patterned to form a patterned mask layer 124 with openings 125. This patterning step prepares the structure for subsequent etching of the underlying material stack to form the final interconnect features.

In one or more embodiments, the patterning step may begin with the application of photoresist material to the surface of the underlayer 104. The photoresist may be then exposed to a specific pattern of light through a photomask using advanced lithography techniques such as deep ultraviolet (DUV) or extreme ultraviolet (EUV) lithography, depending on the critical dimensions required for the interconnect features. After exposure and development of the photoresist, the pattern may be transferred into the underlayer 104 using a selective etching process, such as reactive ion etching (RIE) or other plasma-based dry etching techniques. This etching process may selectively remove portions of the underlayer 104 in areas not protected by the photoresist, creating the patterned mask layer 124 with precisely defined openings 125. The etching chemistry and parameters are carefully optimized to achieve vertical sidewalls and accurate pattern transfer while maintaining critical dimensions.

In various embodiments, the patterned mask layer 124 may serve as a hard mask for subsequent etching of the underlying layers, providing high etch resistance compared to photoresist alone. The openings 125 may define the locations where the metal interconnect features will be formed through the stack of layers including the first adhesion layer 106, the metal layer 108, and the second adhesion layer 110.

In some embodiments, after the formation of the patterned mask layer 124 with openings 125, the photoresist may be removed using oxygen plasma ashing or wet chemical stripping processes to prepare for the subsequent stack etching.

FIG. 1I illustrates an etching process of forming etch features 126 through the openings 125 in the patterned mask layer 124. In various embodiments, the etching process may transform the metal layer 108 into a plurality of metal lines 118, forming the metal interconnects.

In various embodiments, the etching process may use the patterned mask layer 124 as the etch mask, with the openings 125 defining the regions where material will be removed. In one or more embodiments, a multi-step etching sequence may be employed to sequentially remove the different material layers in the stack. The etching process may begin by removing the exposed portions of the first adhesion layer 106, followed by etching through the metal layer 108, and finally through the second adhesion layer 110. This etching sequence may utilize different plasma chemistries optimized for each material to achieve vertical sidewalls, minimal undercut, and precise dimensional control.

In embodiments where the metal layer 108 comprises ruthenium or other noble metals, the etching process may employ oxygen-based or halogen-based plasma chemistries. Refractory metals like tungsten or molybdenum may require fluorine-based etching chemistries. The etching parameters, including RF power, pressure, gas flow rates, and temperature, may be carefully controlled to maintain the integrity of the highly oriented grain structure in the metal layer 108 while achieving clean pattern transfer.

Benefiting from the annealing process 14 described previously, the plurality of metal lines 118 may exhibit low electrical resistance due to the optimized grain structure. The metal lines 118 may show grain structure variations depending on their width relative to the grain size in the original metal layer. In some embodiments, one of the plurality of metal lines 118 may comprise a single grain 16 (or a single-crystalline structure free of grain boundaries) spanning the entire width of the metal line, while another metal line 118 may contain multiple grains 18 with grain boundaries between them.

In embodiments where the metal lines 118 comprising the single grain 16 across their width may minimize electrical resistance by eliminating grain boundary scattering perpendicular to the current flow direction, allowing electrons to travel through a perfect crystalline lattice across the width dimension. In embodiments where the metal lines 118 comprising multiple grains 18 may still benefit from the enlarged grain size and preferred orientation achieved through the high-temperature annealing process, with low density of grain boundaries perpendicular to the current flow direction. These grain boundaries may create scattering sites that slightly increase the electrical resistance compared to single-grain lines. The number and orientation of these grain boundaries depend on the specific line width, the grain size distribution in the metal layer 108, and the alignment between the lithographic pattern and the underlying grain structure.

FIG. 1J illustrates the bonded structure 140 after deposition of a dielectric layer 116 around the metal lines 118, in accordance with an embodiment. This step completes the formation of the interconnect level by providing electrical isolation between the individual metal lines. The dielectric layer 116 may provide electrical isolation between adjacent metal lines 118, preventing unintended current leakage or short circuits.

Following the etching process that defined the metal lines 118, the dielectric layer 116 may be deposited to fill the spaces between adjacent metal lines and provide encapsulation of the bonded structure 140. In various embodiments, the dielectric layer 116 may comprise dielectric materials such as silicon dioxide (SiO₂), silicon nitride (SiN), silicon carbide (SiC), or low-k dielectric materials with dielectric constants below that of silicon dioxide. For advanced applications requiring minimized parasitic capacitance, ultra-low-k materials or even air gaps may be incorporated into the dielectric layer 116.

In various embodiments, the deposition of the dielectric layer 116 may be performed using techniques such as chemical vapor deposition (CVD), plasma-enhanced chemical vapor deposition (PECVD), or atomic layer deposition (ALD) to ensure complete filling of the narrow gaps between metal lines without void formation. For structures with high aspect ratios, specialized deposition techniques such as high-density plasma CVD or flowable CVD may be employed to achieve void-free gap filling. The deposition temperature may be maintained below approximately 400 °C to preserve the integrity of both the metal lines 118 and the underlying active region 114.

In some embodiments, after deposition, the dielectric layer 116 may undergo planarization using chemical-mechanical polishing (CMP) to create a flat surface for subsequent processing. This planarization step may remove excess dielectric material and creates a uniform surface topography for accurate lithography in any additional interconnect levels that may be formed above this layer.

The completed bonded structure 140 features the metal lines 118 with highly oriented grain structures embedded within the dielectric layer 116. The metal lines 118 may provide electrical connections to and between the underlying active region 114, creating the circuit paths necessary for device functionality. The exceptional electrical properties of these metal lines, derived from their optimized grain structure, contribute to improved overall device performance through reduced interconnect resistance and enhanced reliability.

This interconnect level, formed through the wafer-to-wafer transfer of the metal layer 108 comprising oriented grain structures 12, may serve as a first level of a multi-level interconnect stack. In some embodiments, additional interconnect levels may be formed above the bonding structure 140 using either similar wafer-to-wafer transfer approaches or conventional metallization techniques, depending on the specific requirements of each level. The completed interconnect structure may leverage unique advantages of the wafer-to-wafer transfer process to achieve performance characteristics that may be unattainable through conventional direct deposition approaches, particularly for interconnect levels with critical dimensions below 20 nm.

FIGS. 3A and 3B illustrate cross-sectional views of an embodiment surface treatment applied to the metal layer 108 after the annealing process shown in FIG. 1C and before the bonding process shown in FIG. 1E. This surface treatment may address increased surface roughness that may develop during the annealing process.

FIG. 3A shows the first bonding structure 100 after the annealing process in accordance with an embodiment, where the metal layer 108 may exhibit dimples 30 and surface irregularities that have formed during the high-temperature grain growth and reorientation. These surface features may originate from atoms reorganization and grain boundaries migration to form the oriented grain structure. In various embodiments, the dimples 30 may appear as depressions or elevations on the metal surface, corresponding to grain boundary intersections with the surface or to specific crystallographic facets that develop during annealing. In some embodiments, the surface of the metal layer 108 may contain dislocations, atomic-scale defects, or other irregularities that contribute to overall surface roughness. This increased roughness, if left untreated, may compromise the effectiveness of subsequent wafer bonding steps.

In FIG. 3B, the metal layer 108 may be exposed to a plasma 32 to smoothen the surface. In various embodiments, the plasma 32 may be generated from a process gas comprising oxygen, hydrogen, argon, or nitrogen. In an embodiment where the metal layer 108 comprises noble metals like ruthenium, an oxygen-based plasma may be employed. During the plasma treatment, energetic ions in the plasma 32 may physically sputter material preferentially from protrusions on the surface. Moreover, the plasma 32 may induce localized surface diffusion, allowing atoms to redistribute from elevated areas to depressed areas.

In various embodiments, various parameters such as power density, pressure, treatment duration, or gas composition during the plasma treatment may be optimized to achieve effective smoothing without damaging the underlying oriented grain structure or over reducing thickness of the metal layer 108. In some embodiments, the plasma treatment may reduce the surface roughness from several nanometers RMS to below 0.5 nm RMS. The plasma treatment may remove or reduce the dimples 30, dislocations, or other defects at the surface of the metal layer 108 while preserving the beneficial oriented grain structure within the bulk.

In alternative embodiments, the surface of the metal layer 108 may also be smoothened using chemical-mechanical polishing (CMP) with specialized slurries, chemical treatments, or ion beam planarization, depending on the specific metal composition and surface characteristics.

FIGS. 4A and 4B illustrate cross-sectional views of an alternative embodiment that eliminates the second adhesion layer, providing a variation to the process steps shown in FIGS. 1D-1F, in accordance with an embodiment. Unlike the embodiment depicted in FIG. 1D, this variation may not include the deposition of the second adhesion layer 106.

FIG. 4A shows the first bonding structure 100 after the annealing process in FIG. 1C or optional surface treatment in FIG. 3B, with the highly oriented metal layer 108 exposed at the top surface. Without depositing the second adhesion layer 106, the metal layer 108 may be prepared for bonding to the active region 114 directly, which may reduce overall resistance by eliminating an additional interface layer and simplify processing with fewer deposition steps.

FIG. 4B illustrates a bonded structure 440 formed after bonding of the metal layer 108 to the active region 114 on the device wafer 112. Similar to the descriptions with reference to FIG. 1F, the bonding process may bring the two surfaces into intimate contact under controlled temperature and pressure conditions, forming chemical bonds across the interface. In various embodiments, the bonding temperature may remain below 400 °C to maintain compatibility with the thermal budget constraints of the active region 114. The bonding process in FIG. 4A-4B may be particularly advantageous for specific metal and FEOL material combinations that naturally form strong interfacial bonds. For example, certain metals in the metal layer 108 may bond effectively to silicon dioxide surfaces through the formation of metal-oxygen bonds at the interface.

Following the formation of the bonded structure 440, the process flow may continue with steps similar to those shown in FIGS. 1G-1J. In various embodiments, the carrier wafer 102 may be removed using laser lift-off or other separation techniques to expose the underlayer 104. The underlayer 104 may be then patterned to form a hard mask, which is used to etch through the first adhesion layer 106 and the metal layer 108, creating the metal line features similar to the descriptions with reference to FIG. 1I. Finally, a dielectric material may be deposited to fill the spaces between the metal lines and provide electrical isolation.

While FIGS. 1A-4B illustrate the primary process steps for forming highly oriented metal films using wafer-to-wafer transfer, several intermediate steps may be performed between the illustrated stages to ensure optimal process outcomes. In various embodiments, surface cleaning procedures may be implemented before and after steps such as metal deposition, annealing, and bonding to remove contaminants that may compromise interface quality or film properties. These cleaning steps may utilize wet chemical processes with specialized solutions, dry plasma treatments, or combinations thereof, tailored to the specific materials being processed. In various embodiments, process chamber transfer operations between different process tools may be conducted under controlled environments such as vacuum transfer or inert gas ambient to prevent surface oxidation or contamination during wafer movement. In-line metrology and inspection may be performed at multiple points in the process flow to verify film thickness, surface roughness, grain orientation, or other parameters, enabling process adjustments if needed. Additional surface treatments beyond those illustrated, such as hydrogen annealing to remove trace oxides or surface activation processes to enhance bonding energy, may be incorporated depending on specific material requirements. Temperature stabilization periods before and after high-temperature processing may be implemented to minimize thermal stress and ensure uniform temperature distribution across the wafer. These supplementary processes, while not explicitly shown in the figures, may be essential for achieving the high yield and performance consistency required for production implementation of the wafer-to-wafer transfer method.

FIG. 5 illustrates a flowchart of forming metal interconnects through the wafer-to-wafer transfer method, in accordance with an embodiment.

At block 502, a first bonding structure may be provided comprising an underlayer on a carrier wafer, a first adhesion layer deposited on the underlayer, and a metal layer deposited on the first adhesion layer. This step may correspond to the structures and processes described with reference to FIGS. 1A-1B. The carrier wafer may be similar to the carrier wafer 102 described previously, which may comprise silicon with specific crystallographic orientations such as (111) silicon, or alternative materials as detailed in the description of FIG. 1A. The underlayer may be similar to the underlayer 104, which may comprise dielectric materials such as silicon dioxide or silicon nitride deposited using CVD, PECVD, or other deposition techniques. The first adhesion layer may be similar to the first adhesion layer 106, which may comprise materials such as titanium nitride, tantalum nitride, or niobium as described with reference to FIG. 1A. The metal layer may be similar to the metal layer 108, which may comprise ruthenium, molybdenum, tungsten, cobalt, or other refractory metals as discussed with reference to FIG. 1B.

At block 504, the first bonding structure may be processed at elevated temperature to form oriented grain structures in the metal layer. This processing step may correspond to the annealing process 14 described with reference to FIG. 1C. The elevated temperature may range between 800 °C and 1200 °C as previously detailed, with the upper limit selected to avoid potential intermixing between the metal layer and silicon from the carrier wafer. The annealing may be performed using various heating methodologies including substrate holder heating, batch furnace systems, rapid thermal processing, or other techniques as described with reference to FIG. 1C. In some embodiments, the annealing atmosphere may comprise forming gas with 4% hydrogen in nitrogen or other controlled environments to prevent oxidation while promoting grain growth. This processing may transform the disoriented grain structure 10 shown in FIGS. 1B and 2A into the oriented grain structure 12 shown in FIGS. 1C and 2B, with enlarged grain sizes and reduced density of grain boundaries.

At block 506, a second adhesion layer may be deposited on the metal layer. This step may correspond to the structure shown in FIG. 1D, where the second adhesion layer 110 may be deposited on the metal layer 108 with oriented grain structure 12. As described previously, the second adhesion layer may comprise materials similar to those used for the first adhesion layer, such as titanium nitride, tantalum nitride, or niobium. Alternatively, as shown in the variation depicted in FIGS. 4A-4B, this step may be omitted when implementing direct bonding between the metal layer and the active regions.

At block 508, a second bonding structure may be provided comprising an active region formed on a device wafer. This step may correspond to the structure described with reference to FIG. 1E, where the second bonding structure 120 may comprise the device wafer 112 with active region 114. The device wafer may contain active semiconductor devices including transistors, diodes, and other components fabricated using conventional device processing as detailed in the description of FIG. 1E.

At block 510, a bonded structure may be formed by bonding the first bonding structure to the second bonding structure, wherein the second adhesion layer may be bonded to the active region. This bonding step may correspond to the formation of the bonded structure 140 shown in FIG. 1F. As described previously, the bonding process may be performed at temperatures below 400 °C to maintain compatibility with the thermal budget constraints of the active region. Various bonding techniques may be employed including direct bonding, thermocompression bonding, or plasma-activated bonding as detailed in the description of FIG. 1F. In the alternative embodiment shown in FIG. 4B, the metal layer may be directly bonded to the active region to form the bonded structure 440 without using a second adhesion layer.

At block 512, the carrier wafer may be removed from the bonded structure. This step may correspond to the process shown in FIG. 1G, where the carrier wafer 102 may be removed using the wafer grinding process or laser lift-off process. As described in detail with reference to FIG. 1G, the laser lift-off process may employ a laser beam with carefully selected wavelength to create separation at a specific interface, allowing non-destructive removal of the carrier wafer. This approach may enable reuse of the carrier wafer for subsequent processing cycles, providing cost and environmental advantages over destructive removal methods.

At block 514, the underlayer may be etched to form a patterned hard mask layer. This etching step may correspond to the process shown in FIG. 1H, where the underlayer 104 may be patterned to form the patterned mask layer 124 with openings 125. As described previously, this patterning may begin with application of photoresist, followed by lithographic exposure and development, and then etching using techniques such as reactive ion etching to transfer the pattern into the underlayer.

At block 516, the second adhesion layer, the metal layer and the first adhesion layer may be etched using the patterned hard mask layer as an etch mask. This final etching step may correspond to the process shown in FIG. 1I, where the stack may be etched through the openings 125 to form the etch features 126, resulting in a plurality of metal lines 118. As detailed in the description of FIG. 1I, some metal lines may comprise a single grain 16 spanning the entire width, while others may contain multiple grains 18 with grain boundaries between them. Following this etching step, although not explicitly shown in the flowchart, a dielectric layer may be deposited as shown in FIG. 1J to provide electrical isolation between the metal lines.

While not explicitly shown in the flowchart, additional steps may be performed as described in the previous figures. For example, a plasma smoothing process may be applied to the metal layer after annealing, as illustrated in FIGS. 3A-3B, to reduce surface roughness and remove dimples 30 that may form during high-temperature processing. Additionally, variations such as direct bonding without a second adhesion layer, as shown in FIGS. 4A-4B, may be implemented based on specific application requirements and desired material properties.

While the inventive aspects are described primarily in the context of back-end-of-line interconnect formation for integrated circuits, it should also be appreciated that these inventive aspects may also apply to other semiconductor manufacturing applications requiring high-quality metal films. In particular, aspects of this disclosure may similarly apply to through-silicon via (TSV) metallization, advanced packaging interconnects, radio frequency (RF) components, microelectromechanical systems (MEMS), and power semiconductor devices where low-resistance metal films with specific crystallographic orientations may provide performance benefits.

Example embodiments of the invention are described below. Other embodiments can also be understood from the entirety of the specification as well as the claims filed herein.
Example 1. A method for forming a semiconductor device, the method including: depositing a metal layer on a carrier wafer; annealing the metal layer at an elevated temperature to form oriented grain structures in the metal layer; providing a device wafer including an active region; bonding the metal layer to the active region; removing the carrier wafer; and etching the metal layer to form a plurality of metal lines.
Example 2. The method of example 1, further including disposing a dielectric layer around the plurality of metal lines after the etching.
Example 3. The method of one of examples 1 or 2, further including depositing a first adhesion layer between the metal layer and the carrier wafer, where the first adhesion layer includes niobium (Nb) or titanium nitride (TiN).
Example 4. The method of one of examples 1 to 3, further including exposing the metal layer to a plasma to smoothen a surface of the metal layer after the annealing and before the bonding.
Example 5. The method of one of examples 1 to 4, where one of the plurality of metal lines includes a single-crystalline structure free of grain boundaries.
Example 6. The method of one of examples 1 to 5, where the removing includes performing a wafer grinding process or a laser lift-off process.
Example 7. The method of one of examples 1 to 6, where the elevated temperature has a range between 800 °C and 1200 °C.
Example 8. The method of one of examples 1 to 7, where the metal layer includes ruthenium (Ru), molybdenum (Mo), cobalt (Co), or tungsten (W).
Example 9. A method for forming a semiconductor device, the method including: depositing an underlayer on a carrier wafer, a first adhesion layer on the underlayer, and a metal layer on the first adhesion layer; annealing the metal layer at an elevated temperature to form oriented grain structures in the metal layer; bonding the metal layer to an active region of a device wafer; removing the carrier wafer to expose the underlayer; patterning the underlayer to form a patterned hard mask; and etching the metal layer through the patterned hard mask to form a plurality of metal lines.
Example 10. The method of example 9, further including disposing a dielectric layer around the plurality metal lines after the etching.
Example 11. The method of one of examples 9 or 10, where the elevated temperature has a range between 800 °C and 1200 °C.
Example 12. The method of one of examples 9 to 11, further including exposing the metal layer to a plasma to smoothen a surface of the metal layer after the annealing.
Example 13. The method of one of examples 9 to 12, where the removing includes performing a wafer grinding process or a laser lift-off process.
Example 14. The method of one of examples 9 to 13, further including depositing a second adhesion layer on the metal layer after the annealing.
Example 15. The method of one of examples 9 to 14, where one of the plurality of metal lines includes a single-crystalline structure free of grain boundaries.
Example 16. A method for forming a semiconductor device, the method including: providing a first bonding structure including a metal layer on a carrier wafer; annealing the first bonding structure at an elevated temperature to form oriented grain structures in the metal layer; exposing the metal layer to a plasma to smoothen a surface of the metal layer; providing a second bonding structure including an active region on a device wafer; forming a bonded structure by bonding the first bonding structure to the second bonding structure, where the metal layer is bonded to the active region; and removing the carrier wafer and etching the metal layer to form a plurality of metal lines.
Example 17. The method of example 16, where removing the carrier wafer includes performing a wafer grinding process or a laser lift-off process.
Example 18. The method of one of examples 16 or 17, further including depositing an underlayer between the metal layer and the carrier wafer.
Example 19. The method of one of examples 16 to 18, where the removing and the etching include: removing the carrier wafer to expose the underlayer; patterning the underlayer to form a patterned hard mask; and etching the metal layer through the patterned hard mask to form a plurality of metal lines.
Example 20. The method of one of examples 16 to 19, further including disposing a dielectric layer around the plurality metal lines after the etching.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-5 may be combined in further embodiments. It is therefore intended that the appended claims encompass any such modifications or embodiments.

What is claimed is:

1. A method for forming a semiconductor device, the method comprising:
depositing a metal layer on a carrier wafer;
annealing the metal layer at an elevated temperature to form oriented grain structures in the metal layer;
providing a device wafer comprising an active region;
bonding the metal layer to the active region;
removing the carrier wafer; and
etching the metal layer to form a plurality of metal lines.

2. The method of claim 1, further comprising disposing a dielectric layer around the plurality of metal lines after the etching.

3. The method of claim 1, further comprising depositing a first adhesion layer between the metal layer and the carrier wafer, wherein the first adhesion layer comprises niobium (Nb) or titanium nitride (TiN).

4. The method of claim 1, further comprising exposing the metal layer to a plasma to smoothen a surface of the metal layer after the annealing and before the bonding.

5. The method of claim 1, wherein one of the plurality of metal lines comprises a single-crystalline structure free of grain boundaries.

6. The method of claim 1, wherein the removing comprises performing a wafer grinding process or a laser lift-off process.

7. The method of claim 1, wherein the elevated temperature has a range between 800 °C and 1200 °C.

8. The method of claim 1, wherein the metal layer comprises ruthenium (Ru), molybdenum (Mo), cobalt (Co), or tungsten (W).

9. A method for forming a semiconductor device, the method comprising:
depositing an underlayer on a carrier wafer, a first adhesion layer on the underlayer, and a metal layer on the first adhesion layer;
annealing the metal layer at an elevated temperature to form oriented grain structures in the metal layer;
bonding the metal layer to an active region of a device wafer;
removing the carrier wafer to expose the underlayer;
patterning the underlayer to form a patterned hard mask; and
etching the metal layer through the patterned hard mask to form a plurality of metal lines.

10. The method of claim 9, further comprising disposing a dielectric layer around the plurality metal lines after the etching.

11. The method of claim 9, wherein the elevated temperature has a range between 800 °C and 1200 °C.

12. The method of claim 9, further comprising exposing the metal layer to a plasma to smoothen a surface of the metal layer after the annealing.

13. The method of claim 9, wherein the removing comprises performing a wafer grinding process or a laser lift-off process.

14. The method of claim 9, further comprising depositing a second adhesion layer on the metal layer after the annealing.

15. The method of claim 9, wherein one of the plurality of metal lines comprises a single-crystalline structure free of grain boundaries.

16. A method for forming a semiconductor device, the method comprising:
providing a first bonding structure comprising a metal layer on a carrier wafer;
annealing the first bonding structure at an elevated temperature to form oriented grain structures in the metal layer;
exposing the metal layer to a plasma to smoothen a surface of the metal layer;
providing a second bonding structure comprising an active region on a device wafer;
forming a bonded structure by bonding the first bonding structure to the second bonding structure, wherein the metal layer is bonded to the active region; and
removing the carrier wafer and etching the metal layer to form a plurality of metal lines.

17. The method of claim 16, wherein removing the carrier wafer comprises performing a wafer grinding process or a laser lift-off process.

18. The method of claim 16, further comprising depositing an underlayer between the metal layer and the carrier wafer.

19. The method of claim 18, wherein the removing and the etching comprise:
removing the carrier wafer to expose the underlayer;
patterning the underlayer to form a patterned hard mask; and
etching the metal layer through the patterned hard mask to form a plurality of metal lines.

20. The method of claim 16, further comprising disposing a dielectric layer around the plurality metal lines after the etching.
